(19) United States
(12) Patent Application Publication
(10) Pub. No.: US 2011/0284887 A1
(43) Pub. Date: Nov. 24, 2011

(54) LIGHT EMITTING CHIP PACKAGE AND METHOD FOR FORMING THE SAME

(76) Inventors: Shang-Yi WU, Hsinchu City (TW); Tsang-Yu Liu, Zhubei City (TW)

(21) Appl. No.: 12/784,933

(22) Filed: May 21, 2010

(51) Int. Cl. H01L 33/48; H01L 33/00; H01L 33/60

(52) U.S. Cl. 257/91; 257/98; 438/27; 438/28; 257/E33.056; 257/E33.067

(57) ABSTRACT

According to an embodiment of the invention, a light emitting chip package is provided, which includes a carrier substrate having a first surface and an opposite second surface, a cavity extending from the first surface toward the second surface, at least a electrical conductive via and at least a thermal conductive via, located outside of the cavity and penetrating through the first surface and the second surface of the carrier substrate, a light emitting element having contact electrodes and disposed in the cavity, wherein the contact electrode are electrically connected to the electrical conductive via and are electrically insulated from the thermal conductive via.

### BACKGROUND OF THE INVENTION

1. Field of the Invention

The present invention relates to a light emitting chip package and method for forming the same, and in particular relates to a light emitting chip package having electrical conductive vias.

2. Description of the Related Art

A chip package not only provides a connection interface for chips packaged therein, but also provides protection for the chips from environmental contaminants.

With increased functionality, during operation of chips, a large amount of heat may be generated, which negatively affects performance of the chip. Specifically, for LED devices, heat generated during operation may seriously reduce the positive characteristics and lifespan of the LED devices.

Accordingly, a light emitting chip package having good heat dissipation and high structural strength is desired.

### BRIEF SUMMARY OF THE INVENTION

According to an illustrative embodiment, a light emitting chip package is provided. The light emitting chip package comprises a carrier substrate having a first surface and an opposite second surface, a cavity extending from the second surface toward the first surface, at least a electrical conductive via and at least a thermal conductive via, disposed outside of the cavity and penetrating through the first surface and the second surface of the carrier substrate, and a light emitting element having at least a contact electrode and disposed in the cavity, wherein the contact electrode is electrically connected to the electrical conductive via and is electrically insulated from the thermal conductive via.

According to another illustrative embodiment, a method for forming a light emitting chip package is provided. The method for forming a light emitting chip package comprises providing a carrier substrate having a first surface and an opposite second surface, partially removing the carrier substrate to form at least a first hole penetrating from the first surface toward the second surface of the carrier substrate, partially removing the carrier substrate to form at least a second hole penetrating from the first surface toward the second surface of the carrier substrate, thinning the carrier substrate from the second surface of the carrier substrate to expose the first hole and the second hole to form at least a first through-hole and at least a second through-hole, forming a first conducting layer overlying a sidewall of the first through-hole, forming a second conducting layer overlying a sidewall if the second through-hole, and disposing a light emitting element overlying the first surface, wherein the light emitting element has a contact electrode electrically connected to the first conducting layer.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A and 1C-1E are cross-sectional views showing the steps of forming a light emitting chip package according to an embodiment of the present invention;

FIG. 1B is a top view showing the carrier substrate shown in FIG. 1A; and

FIG. 2 shows a top view of a carrier substrate of a light emitting chip package according to an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

It is understood, that the following disclosure provides many difference embodiments, or examples, for implementing different features of the invention. Specific examples of components and arrangements are described below to simplify the present disclosure. These are, of course, merely examples and are not intended to be limiting. In addition, the present disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “overlying,” (and like descriptions) a second layer include embodiments where the first and second layers are in direct contact and those where one or more layers are interposing the first and second layers.

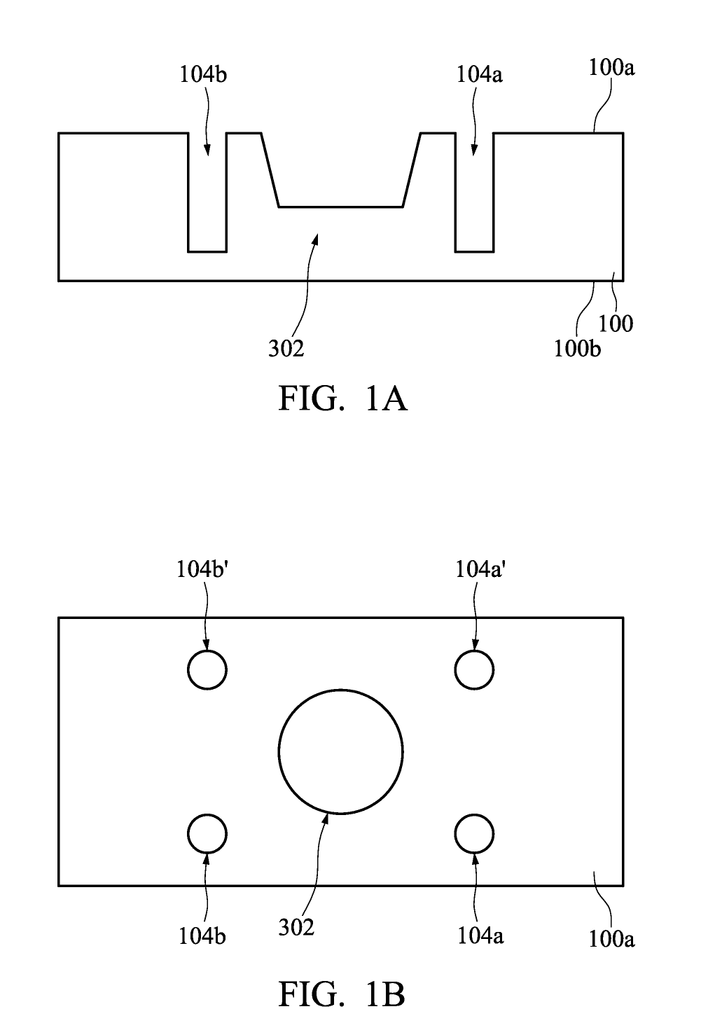

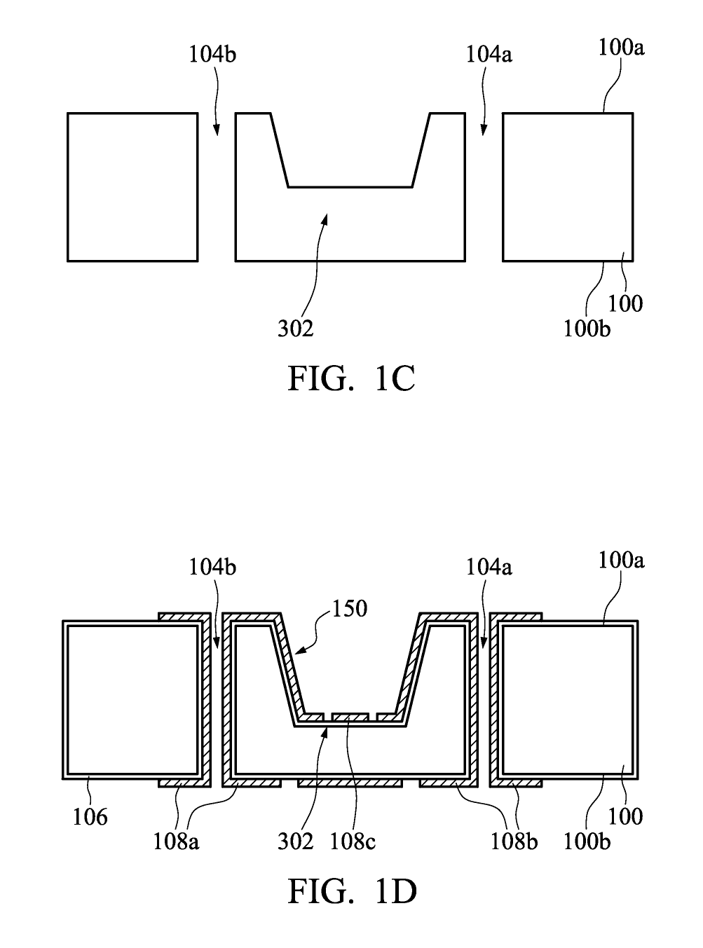

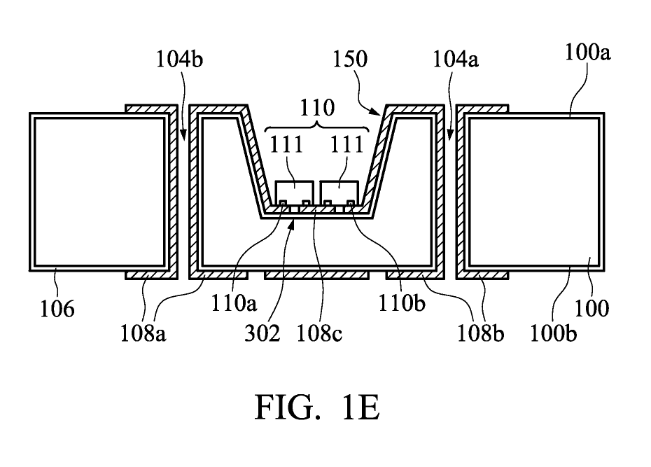

FIGS. 1A and 1C-1E are cross-sectional views showing the steps of forming a light emitting chip package according to an embodiment of the present invention. Referring to FIG. 1A, a carrier substrate 100 having a first surface 100a and an opposite second surface 100b is provided. The carrier substrate 100 may comprise, but is not limited to, a semiconductor material, such as silicon. For example, the carrier substrate 100 may be a silicon wafer. When a silicon wafer is used as the carrier substrate 100, a wafer-level packaging may be proceeded to form a light emitting chip package according to an embodiment of the invention, thus significantly reducing the manufacturing cost and time of the light emitting chip package. In another embodiment, the carrier substrate 100 may be made of other materials, such as aluminum, aluminum nitride, aluminum oxide, or combinations thereof.

FIG. 1B shows a top view of the carrier substrate 100 shown in FIG. 1A. As shown in FIGS. 1A and 1B, the carrier substrate 100 is partially removed to form at least a hole, such as holes 104a and 104a′ and holes 104b and 104b′. The holes 104a, 104a′, 104b, and 104b′ extend from the first surface 100a towards the second surface 100b of the carrier substrate 100. The holes may be formed simultaneously or separately. For example, a photolithography process and an etching process may be performed to partially remove the carrier substrate 100, simultaneously or separately forming the holes 104a, 104a′, 104b, and 104b′.

As shown in FIGS. 1A and 1B, in another embodiment, a cavity 302 extending from the first surface 100a towards the second surface 100b of the carrier substrate 100 is optionally defined in the carrier substrate 100. The bottom portion of the cavity 302 is used to support a light emitting element and the sidewall or the bottom portion of the cavity 302 may be coated with a reflective layer, thus forming a reflective structure surrounding the light emitting element to reflect light emitted from a light emitting element in an upward direction. The cavity 302 may be formed before or after the formation of the holes 104a, 104a′, 104b, and 104b′. Alternatively, the cavity and the holes may be formed simultaneously. In addition, the openings of the holes and the cavity may have any suitable shape, such as circles, rectangles, squares, or the like.

Referring to FIG. 1C, a thinning process is performed on the second surface 100b of the carrier substrate 100 until the holes 104a, 104a′, 104b, and 104b′ are exposed. The thinning process may include, but is not limited to, a chemical mechanical polishing or grinding. After the thinning process, the holes 104a, 104a′, 104b, and 104b′ now become through-holes. Thus, reference numbers 104a and 104a′ are also used to designate the through-holes 104a and 104a′, respectively. Similarly, reference numbers 104b and 104b′are also used to designate the through-holes 104b and 104b′, respectively. A distance between the bottom portion of the cavity 302 and the second surface 100b of the carrier substrate 100 is reduced after the carrier substrate 100 is thinned. In one embodiment, the through-holes surround the cavity 302 and are not under the cavity 302.

Referring to FIG. 1D, an insulating layer 106 is optionally formed on the surface of the carrier substrate 100. The insulating layer 106 may include, but is not limited to, an epoxy resin, solder mask material, or other suitable insulating material, such as inorganic materials including silicon oxide, silicon nitride, silicon oxynitride, metal oxide, or combinations thereof, or organic polymer materials including polyimide, butylcyclobutene (BCB, Dow Chemical Co.), parylene, polynaphthalenes, fluorocarbons, or acrylates and so on. The insulating layer 106 may be formed by a coating method, such as a spin coating, spray coating, or curtain coating method, or other suitable deposition methods, such as a liquid phase deposition, physical vapor deposition, chemical vapor deposition, low pressure chemical vapor deposition, plasma enhanced chemical vapor deposition, rapid thermal chemical vapor deposition, or atmospheric pressure vapor deposition. In one embodiment, the carrier substrate 100 includes silicon. In this case, the insulating layer 106 is preferably a silicon oxide layer formed by a thermal oxidation process. In another embodiment, the carrier substrate 100 is an insulating substrate, such as aluminum nitride substrate or aluminum oxide substrate. In this case, the insulating layer 106 may be omitted.

Still referring to FIG. 1D, a conducting layer is then formed overlying the surface of the carrier substrate 100, and then patterned into a conducting layer 108a extending into the through-hole 104a, a conducting layer 108b extending in to the through-hole 104b, and a redistribution layer 108c, serving as conducting path of the light emitting element. The conducting layer may include, but is not limited to, copper, aluminum, gold, indium tin oxide, or the like. The conducting layer may be formed by a physical vapor deposition, chemical vapor deposition, electroplating, electroless plating, or the like. The conducting layer may be patterned by a patterning process including, for example photolithography and etching processes. In this embodiment, the conducting layer 108a and the conducting layer 108b further extend into the cavity 302, and the redistribution layer 108c is located on the bottom portion of the cavity 302 to serve as a reflective layer 150 of the reflective structure. Thus, a light emitting element disposed on the carrier substrate 100 may receive electrical power from a power source located on the other side of the carrier substrate 100 through the electrical conductive vias. In one embodiment, the light emitting element to be disposed includes a plurality of light emitting diodes electrically connected in series with each other. In this case, the redistribution layer 108c may serve as an electrical bridge between these light emitting diodes.

Although the conducting layer 108a and the conducting layer 108b shown in FIG. 1D are merely conformally formed overlying sidewalls of the through-holes and do not completely fill the through-holes, the embodiment of the invention is not limited to a specific example. In another embodiment, the conductive layer may substantially fill the through-hole completely, depending on the requirement.

Referring to FIG. 1E, a light emitting element 110 is disposed on the bottom portion of cavity 302. The light emitting element 110 may include, but is not limited to, a light emitting diode, OLED, PLED, or the like. The light emitting element 110 includes a first contact electrode 110a and a second contact electrode 110b used for receiving electrical power. The first contact electrode 110a and the second contact electrode 110b may be located on the same side of the light emitting element 110. In another embodiment, the first contact electrode 110a and the second contact electrode 110b may be located on different sides of the light emitting element 110.

Further, when the light emitting element 110 is a light emitting diode, the first contact electrode 110a has a conductivity type opposite to that of the second contact electrode 110b. In one embodiment, the first contact electrode 110a is a p-type electrode and the second contact electrode 110b is an n-type electrode. In another embodiment, the first contact electrode 110a is an n-type contact electrode and the second contact electrode 110b is a p-type electrode.

In one embodiment, the light emitting element 110 includes a plurality of light emitting diodes 111. These light emitting diodes 111 are electrically connected in series with each other, such as that shown in FIG. 1E. One of the light emitting diodes 111 may be electrically connected to another light emitting diode 111 through a bonding wire or the redistribution layer 108c previously defined on the carrier substrate 100. In one embodiment, the light emitting element 110 includes any array of a plurality of light emitting diodes 111 electrically connected in series with each other.

In the embodiment shown in FIG. 1E, the first contact electrode 110a of the light emitting element 110 directly contacts with the conducting layer 108a extending overlying the bottom portion of the cavity 302 while the second contact electrode 110b of the light emitting element 110 directly contacts with the conducting layer 108b extending overlying the bottom portion of the cavity 302. The light emitting element 110 may include a plurality of light emitting diodes 111 electrically connected in series with each other. In this case, a large amount of electrical current passes through the light emitting element 110 during operation.

In addition, the conducting layer 108a and the conducting layer 108b extending and overlying the sidewall of the cavity 302 may not only be used to provide electrical power to the light emitting element 110 but also serve as the reflective layer 150 to reflect light emitted from the light emitting element 110 in an upward direction. In other words, the conducting layer 108a and the conducting layer 108b may also be used as reflective layers. In this case, the conducting layer 108a and the conducting layer 108b are preferably made of a conducting material having a high reflectivity, such as aluminum, silver, copper, or the like. In another embodiment, an additional reflective layer may additionally formed overlying the conducting layer 108a and the conducting layer 108b in the cavity 302 to serve as a reflective structure.

Referring to FIGS. 1E and 1B, the first contact electrode 110a of the light emitting element 110 is electrically connected to two electrical conductive vias (the combination of the through-holes 104a and 104a′ and the conducting layer 108a) and the second contact electrode 110b of the light emitting element 110 is electrically connected to two electrical conductive vias (the combination of the through-holes 104a and 104b and the conducting layer 108b). Thus, high electrical current passing through the light emitting element 110 is shared by a plurality of electrical conductive vias, significantly improving the reliability of the light emitting chip package. Sometimes, electrical connection between one of the electrical conductive via and the light emitting element may not be established successfully due to process error. Because there are at least two electrical conductive vias are designed to be electrically connected to the contact electrode of the light emitting element, even if one of the electrical conductive via fail to be electrically connected to the contact electrode of the light emitting element, the other electrical conductive via can still be used to provide electrical path between the power source and the light emitting element.

In this embodiment, the electrical conductive vias are preferably disposed outside the region surrounded by the reflective structure (the combination of the cavity and the conducting layer). Heat generated from the electrical conductive vias and heat generated from the light emitting element 110 are not accumulated in the cavity where the light emitting element 110 is disposed, significantly improving heat dissipation.

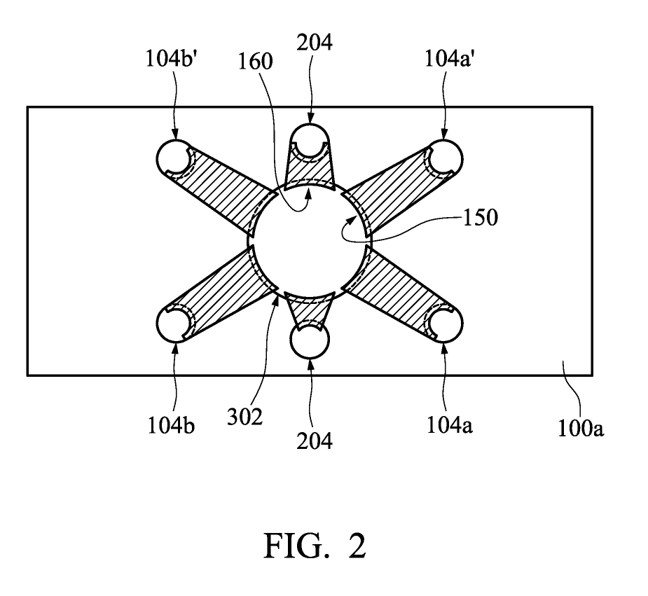

In one embodiment, at least a thermal conductive vias may further be formed in the carrier substrate to further improve heat dissipation of the light emitting chip package. FIG. 2 shows a top view of a carrier substrate of a light emitting chip package according to an embodiment of the invention. In this embodiment, additional thermal holes 204 are defined in the carrier substrate 100 by a method similar to the holes and cavity shown in FIG. 1. Then, similar to that shown in FIG. 1D, conducting layer is coated on sidewalls of the holes including the thermal holes 204, forming at least a thermal conductive via. The conducting layer extends overlying the sidewall or the bottom portion of the cavity to further dissipate heat away from the cavity and to prevent heat to be accumulated in the bottom portion of the cavity or the substrate thereunder. Thus, the thermal conductive via may facilitate heat dissipation of the light emitting chip package. In one embodiment, the conducting layer used for heat dissipation may serve as another reflective layer 160 which is electrically insulated from the contact electrode and the electrical conductive via to prevent short. The position and distribution of the thermal conductive via can be in any type depending on the requirement.

As described above, according to an embodiment of the present invention, a light emitting chip package may be provided with a plurality of electrical conductive vias, which are formed to share high electrical current passing through a light emitting element or serve as backup electrical conductive via. In another embodiment, the electrical conductive via and the additionally formed thermal conductive via are both located outside a region surrounded by a cavity and not in the substrate under the cavity. Thus, in addition to the improved strength of the carrier substrate, heat dissipation and reliability of the light emitting chip package is enhanced. Accordingly, a light emitting chip package having good heat dissipation and structural strength is achieved.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light emitting chip package, comprising:
a carrier substrate having a first surface and an opposite second surface;
a cavity extending from the first surface toward the second surface;
at least a electrical conductive via and at least a thermal conductive via, located outside of the cavity and penetrating through the first surface and the second surface of the carrier substrate; and
a light emitting element having at least a contact electrode and disposed in the cavity, wherein the contact electrode is electrically connected to the electrical conductive via and is electrically insulated from the thermal conductive via.

2. The light emitting chip package as claimed in claim 1, wherein the light emitting element comprises a light emitting diode.

3. The light emitting chip package as claimed in claim 1, wherein the light emitting element comprises a plurality of light emitting diodes electrically connected in series with each other.

4. The light emitting chip package as claimed in claim 1, further comprising a reflective structure surrounding the light emitting element.

5. The light emitting chip package as claimed in claim 4, wherein the light emitting element is disposed on a bottom portion of the cavity, and the reflective structure is located on the bottom portion or a sidewall of the cavity.

6. The light emitting chip package as claimed in claim 5, wherein the reflective structure comprises a first reflective layer and a second reflective layer, electrically insulated from each other.

7. The light emitting chip package as claimed in claim 6, wherein the first reflective layer and the second reflective layer are made of a metal material.

8. The light emitting chip package as claimed in claim 7, wherein the first reflective layer is electrically connected to the contact electrode and the electrical conductive via.

9. The light emitting chip package as claimed in claim 8, wherein the second reflective layer is connected to the thermal conductive via and is electrically insulated from the contact electrode and the electrical conductive via.

10. A method for forming a light emitting chip package, comprising:
providing a carrier substrate having a first surface and an opposite second surface;
partially removing the carrier substrate to form at least a first hole extending from the first surface towards the second surface of the carrier substrate;
partially removing the carrier substrate to form at least a second hole extending from the first surface towards the second surface of the carrier substrate;
thinning the carrier substrate from the second surface of the carrier substrate to expose the first hole and the second hole to form at least a first through-hole and at least a second through-hole;
forming a first conducting layer overlying a sidewall of the first through-hole;
forming a second conducting layer overlying a sidewall of the second through-hole; and
disposing a light emitting element overlying the first surface, wherein the light emitting element has a contact electrode electrically connected to the first conducting layer.

11. The method for forming a light emitting chip package as claimed in claim 10, wherein the first conducting layer in the first through-hole serves as a electrical conductive via, and the second conducting layer in the second through-hole serves as a thermal conductive via, and wherein the thermal conductive via is electrically insulated from the electrical conductive via and the contact electrode, respectively.

12. The method for forming a light emitting chip package as claimed in claim 11, further comprising:
forming a cavity extending from the first surface towards the second surface;
disposing the light emitting element overlying a bottom portion of the cavity; and
forming a reflective structure overlying a sidewall or a bottom portion of the cavity.

13. The method for forming a light emitting chip package as claimed in claim 12, wherein the reflective structure comprises a first reflective layer and a second reflective layer, electrically insulated from each other.

14. The method for forming a light emitting chip package as claimed in claim 13, wherein the first through-hole and the second through-hole surround the cavity.

15. The method for forming a light emitting chip package as claimed in claim 12, wherein the cavity, the first hole, and the second hole are formed simultaneously.

16. The method for forming a light emitting chip package as claimed in claim 10, wherein the first hole and the second hole are formed simultaneously.

17. The method for forming a light emitting chip package as claimed in claim 13, wherein the first conducting layer and the second conducting layer extend overlying the sidewall or the bottom portion of the cavity to serve as the first reflective layer and the second reflective layer, respectively.

18. The method for forming a light emitting chip package as claimed in claim 10, wherein the light emitting element comprises a plurality of light emitting diodes electrically connected in series with each other.
